(19) United States
(12) Patent Application Publication
(10) Pub. No.: US 2025/0378248 A1
(43) Pub. Date: Dec. 11, 2025

(54) METHOD FOR RELIABILITY PREDICTION AND ELECTRONIC CIRCUIT

(71) Applicant: Infineon Technologies Austria AG, Villach (AT)

(72) Inventors: Manuel HOLLFELDER, München (DE); Christian BERNHARDT, Erding (DE); Yosra BAHRI, München (DE); Monideep BORA, Ottobrunn (DE); Jianyu ZHAO, München (DE)

(21) Appl. No.: 19/222,426

(22) Filed: May 29, 2025

(30) Foreign Application Priority Data
Jun. 10, 2024 (DE) 102024116095.0

(51) Int. Cl. G06F 30/3308

(52) U.S. Cl. CPC G06F 30/3308

(57) ABSTRACT

According to an embodiment, a method is provided, comprising:
repeatedly performing a measurement of a plurality of operation parameters of an electronic circuit during operation of the electronic circuit,
for each measurement calculating, by the electronic circuit, a reliability prediction parameter of the electronic circuit based on the measurements and a reliability prediction model of the electronic circuit.

### RELATED APPLICATIONS

This application claims priority to earlier filed German Patent Application Serial Number 102024116095.0, filed on Jun. 10, 2024, the entire teachings of which are incorporated herein by this reference.

### BACKGROUND

Electronic components and circuits may fail when in use after a certain time, which may vary from component to component and from circuit to circuit for example due to process variations and different stress (for example temperature stress or electrical stress) experienced in use. The point in time when a particular component or circuit fails is difficult, if not impossible to predict precisely. However, the failure rate of electronic components generally follows a “bathtub” curve, which is illustrated in FIG. 1.

A curve 10 in FIG. 1 shows the failure rate over time. Roughly speaking, such a failure rate is made up of three components, shown in curves 11-13. Such a curve can be described, e.g., by a Weibull distribution or other models.

Curve 11 illustrates the so called “infant mortality” failure, i.e. a failure of circuits or components in a circuit in an early stage of the deployment. This contribution becomes mostly negligible after a certain time, e.g. one year as shown in FIG. 1. These early failures may for example be due to small defects or other issues caused during production, which are not detected in an after production test, but lead to early failures. Curve 12 illustrates so called wear out failures, which are the result of stress experienced by the components or circuits over time. This curve typically increases strongly after a lifetime guaranteed by a manufacturer has expired, or, in other words, the manufacturer indicates a lifetime as marked in FIG. 1, where curve 12 is still low. The third contributor is showed in curve 13, namely constant random failures, the rate of which stays essentially constant.

One way to quantify the failure rate is using mean time between failures (MTBF) or mean time to failures (MTTF) or as its inverse A=1/MTBF or A=1/MTTF. In general, MTBF is used for repairable devices between failures while MTTF is used for non-repairable devices.

Generally, customers require certain guarantees regarding the lifetime of electronic components, for example that a maximum of XX % of the components may fail during the first YY years, where lower numbers for XX and higher numbers for YY usually correspond to more costly components.

However, while the failure rate increases after the guaranteed lifetime, this does not mean that the components suddenly fail. In fact, the lifetime guaranteed by a manufacturer is to some extent based on a worst-case scenario for example regarding stress experienced by the component or circuit, to be able to really guarantee corresponding operation. However, if for example the stress on a device is low, for example operation occurs at lower temperatures, less switching cycles occur, lower currents are experienced etc., the time before a failure occurs may be significantly higher, or, in other words, the device may be operated for a considerably longer time, probably longer time than the guaranteed lifetime indicated by the manufacturer. The same holds true for electronic circuits including a plurality of components (where, unless components are provided redundantly, the first device to fail also causes a failure of the circuit as a whole). The reverse is also true, i.e. with exceptionally high stress the lifetime may be shorter.

### BRIEF DESCRIPTION

According to an embodiment, a method is provided, comprising:
repeatedly performing a measurement of a plurality of operation parameters of an electronic circuit during operation of the electronic circuit, and,
for each measurement, calculating, by the electronic circuit, a reliability prediction parameter based on the measurement and a reliability prediction model of the electronic circuit.

According to another embodiment, an electronic circuit is provided, comprising:
measurement circuitry configured to measure a plurality of operation parameters of the electronic circuit, and
a calculation logic configured to repeatedly calculate a reliability prediction parameter for the electronic circuit based on a respective measurement of the plurality of operation parameters and a reliability prediction model of the electronic circuit.

The above summary is merely a brief overview over some features of some embodiments and is not to be construed as limiting in any way, as other embodiments may include different features than the ones given above.

### BRIEF DESCRIPTION OF THE DRAWINGS

FIG. 1 is a diagram illustrating failure rates over time.

FIG. 2 is a flowchart of a method according to an embodiment.

FIG. 3 is a block diagram of an electronic circuit according to an embodiment.

FIG. 4 is a circuit diagram of an electronic circuit according to an embodiment.

FIG. 5 is a graph illustrating cumulative distribution function for illustrating some embodiments.

FIG. 6A is a diagram illustrating methods and electronic circuits according to some embodiments, and FIGS. 6B and 6C serve for illustrating the embodiment of FIG. 6A further.

FIGS. 7A and 7B illustrate histograms output in some embodiments.

FIGS. 8 and 9 are failure probability graphs for illustrating some embodiments.

FIG. 10 is a diagram illustrating grouping of components and assigned operation parameters of some embodiments.

### DETAILED DESCRIPTION

In the following, various embodiments will be described in detail referring to the attached drawings. These embodiments are given by way of example only and are not to be construed as limiting in any way.

Features from different embodiments may be combined to form further embodiments. Variations, modifications or details described with respect to one of the embodiments are also applicable to other embodiments and will not be described repeatedly.

Some terms used herein will be explained in the following.

An electronic circuit is to be understood as a device including a plurality of electronic components, also referred to simply as components or as devices, electrically interconnected with each other. Moreover, the electronic circuit may additionally include electro-mechanical or mechanical components or devices. Such components may include for example resistors, inductors, which may be combined to form transformers, capacitors, optoelectronic- and RF-devices, electro-mechanical components such as MEMS sensors, transistors or other semiconductor devices, or integrated circuits, mechanical connectors, heat exchangers, or rotating devices such as fans or hard disks. An electronic circuit as used herein may be provided in a single housing, package or on a single circuit board, but may also be provided in two or more housings, packages and/or on two or more circuit boards interconnected with each other.

An operation parameter is a parameter describing conditions under which the electronic circuit operates, i.e. measurable characteristics of the operation of the electronic circuit. They can be parameters fully or partially caused by the operation of the electronic circuit itself like voltages, currents, or temperature (by self-heating through the operation). They may also include environmental parameters like humidity, air pressure, corrosive gases, ambient temperature or also mechanical parameters like vibrations or other kinds of mechanical stress.

Embodiments discussed herein relate to determining of a reliability prediction parameter for an electronic circuit. A reliability prediction parameter generally relates to a parameter which gives some indication of the likelihood of the electronic circuit experiencing a failure, or indication related thereto. For example, the reliability prediction parameter may give a mean time between failures (MTBF), the reverse thereto, usually designated λ (λ=1/MTBF), a failure rate, a failure probability, a remaining lifetime estimation or the like.

A reliability prediction model is a model which may be used by a calculation logic to determine a reliability prediction parameter based on operation parameters of a circuit. Such models and calculation methods employable by such calculation logics are standardized by various standards like Telcordia SR-332, MIL-HDBK-217F, ANSI/VITA 51.1, NPRD/EPRD, IEC 61709, Siemens SN 29500, IEC-TR-62380, FIDES, 217Plus or GJB/Z 299C and GJB/Z 299B for reliability prediction models and calculation methods.

Generally, to obtain a reliability prediction model for a circuit, corresponding reliability prediction models for individual components of the circuit may be combined. In some embodiments, operation parameters will be measured on circuit level, i.e. not individually for the components, but then used to determine reliability prediction values for the individual components, which are then combined to a reliability prediction parameter for the electronic circuit.

Examples will be discussed further below in detail.

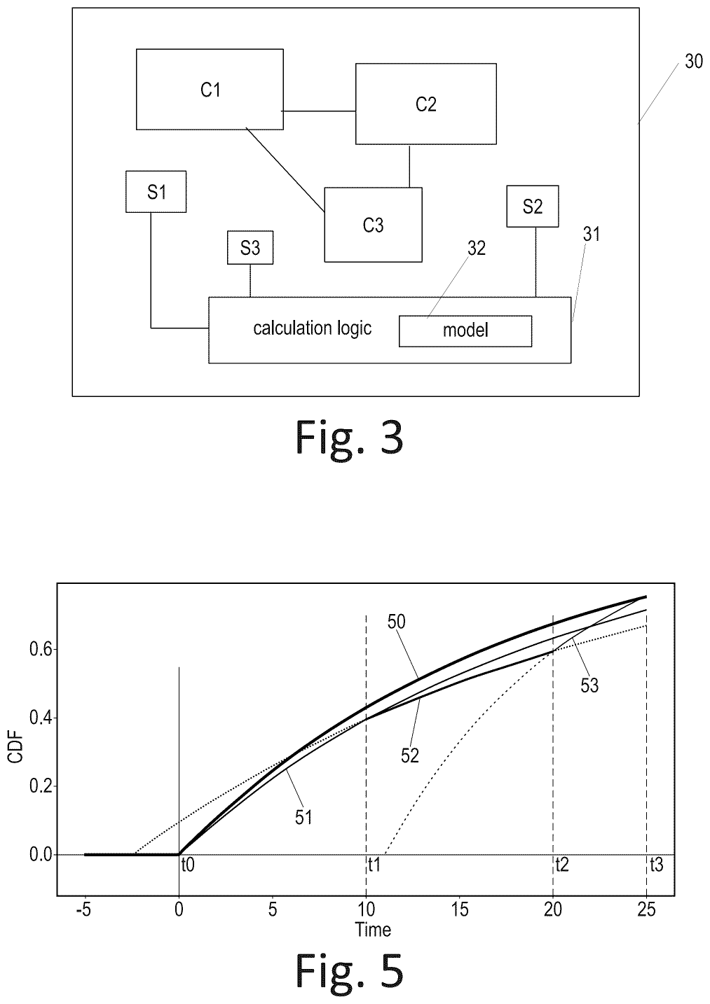

FIG. 2 is a flowchart illustrating a method according to an embodiment, and FIG. 3 shows a block diagram of an electronic circuit 30 according to an embodiment. While for better understanding the method of FIG. 2 will be described in conjunction with the electronic circuit of FIG. 3, it is to be understood that the method of FIG. 2 may also be implemented in other circuits.

At 20, the method of FIG. 2 comprises performing measurements of operation parameters of an electronic circuit during a circuit operation. As an example, FIG. 3 illustrates an electronic circuit including components C1, C2, C3 electrically interconnected with each other. The number of three components and their interconnection is merely a simple example, and the number of components of electronic circuit 30 is not particularly limited. Furthermore, electronic circuit 30 may comprise one or more sensors, in the example of FIG. 3 sensors S1, S2, S3, for measuring operation parameters. To give an example, sensor S1 may be a temperature sensor, sensor S2 may be a current sensor, and sensor S3 may be a voltage sensor, sensors S2 and S3 measuring a current and voltage respectively, supplied to circuit 30, provided by circuit 30, or within electronic circuit 30. In other embodiments, other kinds of sensors or several sensors of the same type, for example two or more temperature sensors, two or more current sensors or two or more voltage sensors, may be provided.

The term sensor as used herein is to be interpreted broadly and refers to any entity capable of measuring a corresponding operation parameter. For example, any conventional temperature sensors or approaches for measuring currents or voltages may be used. Measurements may also be indirect measurements.

Sensors S1, S2, S3 measure parameters on circuit level in some embodiments, for example do not measure individual parameters like individual temperatures of components C1, C2, C3, but in some embodiments only a single temperature is measured, which is then used as temperature of the circuit as a whole. Similar considerations may apply for currents and voltages. For example, input and output voltages or currents of the circuit may be measured, but no voltages and currents for each individual component C1, C2, C3. As will be explained further below in more detail, from such circuit-level operation parameters component-level operation parameters for the individual components may be estimated in some embodiments.

Returning now to FIG. 2, at 21 a reliability prediction parameter for the electronic circuit is calculated based on a reliability prediction model of the circuit and based on measurements. To this end, in FIG. 3 the measurement results from sensors S1, S2, S3 are provided to a calculation logic 31 which uses reliability prediction model 32. In FIG. 3, calculation logic 31 is part of the electronic circuit, such that the calculation of the reliability prediction parameter is performed within the electronic circuit. In some embodiments, this enables an in-situ monitoring.

Calculation logic 31 may be implemented in hardware, software, firmware or any combination thereof to perform the calculations described herein. Calculation logic 31 may be a dedicated component of electronic circuit 30 used only for calculating the reliability prediction parameter and related tasks, but in other embodiments may also be a component also used for other purposes. As an example, calculation logic 31 may be a controller like a microcontroller controlling operation of electronic circuit 30, and additionally used for calculating the reliability prediction parameter.

At 22, the method of FIG. 2 further comprises outputting, monitoring and/or processing the reliability prediction parameter. For instance, based on the process reliability prediction parameter a warning may be output when a failure probability of the electronic circuit exceeds a predefined threshold value. More possibilities will be explained further below.

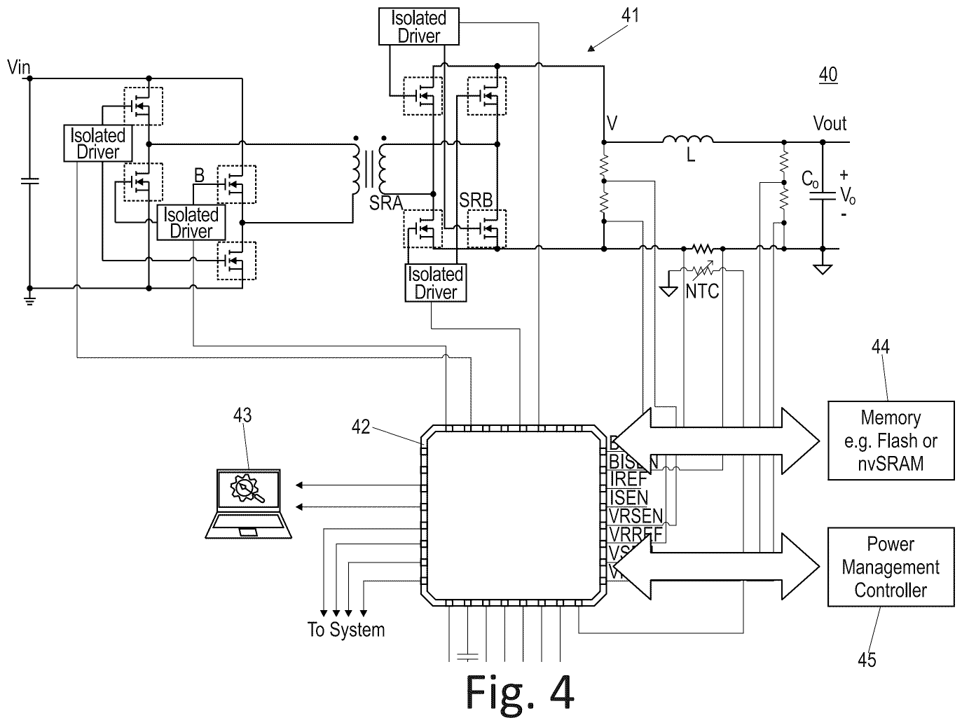

Before discussing calculating the reliability prediction parameter in more detail, a specific circuit example will be discussed referring to FIG. 4. FIG. 4, as an example for an electronic circuit 40, shows a power converter 40 including power converter circuitry 41. Power converter circuitry 41 receives an input voltage Vᵢₙ and converts the input voltage Vᵢₙ to an output voltage Vₒᵤₜ by selectively providing energy to a primary side winding of a transformer. A secondary side winding of the transformer is coupled to an output outputting the voltage Vₒᵤₜ. Furthermore, power converter 40 comprises a controller 42 controlling for example transistors of the power converter. Controller 42 furthermore serves as an example for a calculation logic. For instance, controller 42 receives voltage, current and/temperature information from power converter circuitry 41 (for example a measurement of input voltage Vᵢₙ and output voltage Vₒᵤₜ) and calculates a reliability prediction parameter based on these measurements and a reliability prediction model of power converter 40.

The calculated reliability prediction parameter then may be stored in a memory 44, output to a power management controller 45 which may, based on the reliability prediction parameter, for example perform load balancing between various power converters, and/or may provide the reliability prediction parameter to a terminal 43 to be accessed by a user. Such a load balancing for “reliability balancing” can be combined with a conventional load balancing to fulfill for example load requirements. To this end, for example a load conventional load balancing controller with a faster regulation may be combined with “reliability balancing” with a slower regulation speed. Besides load balancing, also other kinds of controlling the electronic circuit, e.g. power converter 40, based on the reliability parameter are possible, for example power throttling (reducing the power output), switching-off of the electronic circuit, lowering performance (e.g. slower dynamic response, mode requiring less electrical power leading to lower stress).

It should be noted that circuit-level operation parameters in many applications, like power converter 40 shown in FIG. 4, are measured by a corresponding controller like controller 42 anyway. For example, output voltage and input voltage may be measured for controlling the power converter, for example for regulating the output voltage to a desired value and/or for power factor correction purposes. Therefore, in such cases no or only little additional measurement circuitry, for example sensors, are necessary for measuring circuit-level parameters.

Next, calculating a reliability prediction parameter will be discussed in more detail.

Traditionally, reliability models which are defined in various standards, like the standards mentioned above, are used for giving a lifetime assessment of a circuit for example during the development phase, for example to compare different designs. In contrast thereto, embodiments discussed herein use the reliability prediction models in a dynamic manner, by measuring operation parameters (also referred to as mission profiles) directly during operation of the circuit and calculating a corresponding reliability prediction parameter, which thus may be updated based on repeated measurements. As an example, an approach based on the Telcordia SR-332 standard will be discussed below. Similar approaches may be used for other standards.

According to this standard, the failure rate

$${λ}_{{comp}_{i}}^{acc}$$

of a component i may be given by

$${λ}_{{comp}_{i}}^{acc} = {λ}_{{comp}_{i}} {π}_{{temp}_{i}} {π}_{{stress}_{i}} {π}_{{quality}_{i}} \qquad ( 1 )$$

λ_{comp}_{ᵢ} is a basic reliability description for component i which corresponds to an expected reliability of this component. λ_{comp}_{ᵢ} is expressed as mean generic steady-state failure rate for component i in the Telcordia SR-332 standard. λ_{comp}_{ᵢ} may be based on the design of the electronic circuit and based on knowledge of the manufacturer of the component.

The π factors are so called acceleration factors. π_{quaity}_{ᵢ} is a quality factor of the component which is based on the manufacturing, testing, and quality assurance processes at the manufacturer. In embodiments of the present application, λ_{comp}_{ᵢ} and π_{quality}_{ᵢ} are fixed parameters, which may for example be provided by a manufacturer of the component and/or designer of the electronic circuit. πₜₑₘₚ_{ᵢ} describes an influence of temperature stress and may be adapted based on temperature measurements, and πₛₜᵣₑₛₛ_{ᵢ} is an acceleration factor indicative of electric stress, which may be estimated based on current, voltage and/or electrical power measurements. Therefore, in embodiments these essentially are dynamic parameters which are adapted based on measurements.

Such an approach, using a basic reliability description and acceleration factor is used in many of the standards mentioned above.

From the above reliability values for the individual components, a reliability prediction parameter λ_{sys} for the electronic circuit in this case may be calculated according to

$${λ}_{sys} = {π}_{env} {\sum }_{i}^{N} {λ}_{{comp}_{i}} {π}_{{temp}_{i}} {π}_{{stress}_{i}} {π}_{{quality}_{i}} = {π}_{env} {\sum }_{i}^{N} {λ}_{{comp}_{i}}^{acc} \qquad ( 2 )$$

where the sum is generated over N components of the electronic circuit, and πₑₙᵥ is an acceleration factor representing the environment, for example environment humidity and similar issues.

For this formula, a series model is chosen which means that if one component fails, the whole electronic circuit will fail. This has the advantage that the individual component failure rates can be summed up as shown above. If this is not the case (i.e. a series model is not applicable), the above formula needs to be modified. For example, if components are provided redundantly, such that the overall electronic circuit fails only when all of M redundant components fail, this may be reflected in a modification the mentioned equation (2) accordingly.

$${λ}_{{comp}_{i}}^{acc}$$

will be referred to as the accelerated basic reliability description factor for component i herein and may be defined as follows:

$${λ}_{{comp}_{i}}^{acc} = {λ}_{{comp}_{i}} {π}_{{temp}_{i}} {π}_{{stress}_{i}} {π}_{{quality}_{i}} = {λ}_{{comp}_{i}} {π}_{{quality}_{i}} {e}^{\frac{{E}_{{a}_{i}}}{k} ( \frac{1}{{T}_{{i}_{0}}} - \frac{1}{{T}_{i}} )} {e}^{{m}_{i} ( {p}_{i} - {p}_{{i}_{0}} )} \qquad ( 3 )$$

Here, the calculation method for the acceleration factors for temperature and electrical stress, namely

$${π}_{{temp}_{i}} = {e}^{\frac{{E}_{{a}_{i}}}{k} ( \frac{1}{{T}_{{i}_{0}}} - \frac{1}{{T}_{i}} )}$$

and πₛₜᵣₑₛₛ_{ᵢ}=e^{m}^{ⁱ}^{(p}^{ⁱ}^{-pi}^{⁰}⁾ are defined in Telcordia SR-332, and other corresponding standards use similar definitions as they follow similar underlying acceleration theory like Arrhenius' law. In the above expression, Eₐ_{ᵢ} is a component specific activation energy, Tᵢ is the temperature of component i, Tᵢ_{ₒ} is a reference temperature, k is the Boltzmann constant. mᵢ is a component specific curve parameter, pᵢ is an electrical stress parameter, which is defined for example in Telcordia SR-332 depending on the component as the ratio (also named electrical stress percentage according to Telcordia SR-332) of an applied value and a rated value, for example for resistors

$$p = \frac{applied power}{rated power}$$

or for capacitors

$$p = \frac{applied voltage}{rated voltage} .$$

pᵢ_{ₒ} a reference stress parameter according to Telcordia SR-332. The electrical stress can be written as

$${p}_{i} = \frac{{α}_{i}}{{γ}_{i}}$$

with αᵢ the component i or device i specific applied value, for example current or power or other similar electrical quantity, which can be measured, and similarly γᵢ the component or device i specific rated value.

As defined in Telcordia SR-332 and in other reliability standards as well, acceleration factors can itself be the product of multiple factors. As an example, the electrical stress πₛₜᵣₑₛₛ_{ᵢ}=e^{m}^{ⁱ}^{(p}^{ⁱ}^{-pi}^{⁰}⁾ for component or device i can itself be the product of electrical stress factors if multiple stress factors apply to a component or device simultaneously,

as an example

$${n}_{{stress}_{i}} = {\prod }_{k} {π}_{{stress}_{i}}^{k} = {\prod }_{k} {e}^{{m}_{i}^{k} ( {p}_{i}^{k} - {p}_{{i}_{0}}^{k} )}$$

with k denoting the index of the respective stress factor of the product. The following methods and principles can be applied with respective adoptions and without loss of generality.

The above equation (3) for the reliability description factors can therefore be rewritten as

$$ln ( {λ}_{{comp}_{i}}^{acc} ) = ln ( {λ}_{{comp}_{i}} {π}_{{quality}_{i}} ) + ln ( {e}^{\frac{{E}_{{a}_{i}}}{k} ( \frac{1}{{T}_{{i}_{0}}} - \frac{1}{{T}_{i}} )} ) + ln ( {e}^{{m}_{i} ( {p}_{i} - {p}_{{i}_{0}} )} ) \qquad ( 4 )$$

where ln is the natural logarithm. With the above rewriting of the parameters pᵢ using the values αᵢ and γᵢ, equation (4) can be rewritten as

$${μ}_{i} := ln ( {λ}_{{comp}_{i}}^{acc} ) = ln ( {λ}_{{comp}_{i}} {π}_{{quality}_{i}} ) + \{ \frac{{E}_{{a}_{i}}}{k} ( \frac{1}{{T}_{{i}_{0}}} - \frac{1}{{T}_{i}} ) \} + \{ {m}_{i} ( \frac{{α}_{i}}{{γ}_{i}} - \frac{{α}_{{i}_{0}}}{{γ}_{i}} ) \} \qquad ( 5 )$$

As can be seen from the above equations, μᵢ depends on parameters which are fixed for a given component, and on parameters depending on the environment/operation parameters, like temperatures and electrical stress. For N components, the above equation (5) may be written in matrix form as

$$( \begin{matrix}{μ}_{1} \\ ⋮ \\ {μ}_{N}\end{matrix} ) := ( \begin{matrix}ln ( {λ}_{{comp}_{1}} {π}_{{quality}_{1}} ) & \frac{{E}_{{a}_{1}}}{k} & … & 0 & \frac{{m}_{1}}{{γ}_{1}} & … & 0 \\ ⋮ & ⋮ & ⋱ & 0 & 0 & ⋱ & 0 \\ ln ( {λ}_{{comp}_{N}} {π}_{{quality}_{N}} ) & 0 & … & \frac{{E}_{{a}_{N}}}{k} & 0 & … & \frac{{m}_{N}}{{γ}_{N}}\end{matrix} ) ( \begin{matrix}1 \\ \frac{1}{{T}_{{1}_{0}}} - \frac{1}{{T}_{1}} \\ ⋮ \\ \frac{1}{{T}_{{N}_{0}}} - \frac{1}{{T}_{N}} \\ {α}_{1} - {α}_{{1}_{0}} \\ ⋮ \\ {α}_{N} - {α}_{{N}_{0}}\end{matrix} ) \text{=:} M \cdot S \qquad ( 6 )$$

In this way, for the calculation of the values

$${μ}_{i} = ln ( {λ}_{{comp}_{i}}^{acc} )$$

for all components i=1 . . . N, a matrix multiplication between a matrix M which is a static matrix depending on the components used, also referred to as bill of materials (BOM), and a vector S representing the operation parameters, can be used. The vector S may also be referred to as a dynamic stress vector.

The size of the matrix M in a system with N components is N×2N+1, and the size of the column vector S is 2N+1×1. By calculating all μ₁ for i=1 . . . N finally based on the above equations the reliability prediction parameter λ_{sys} may be calculated by applying the environmental factor according to λ_{sys}=πₑₙᵥΣᵢe^{μ}^{ᵢ}. It should be emphasized that this approach may also be applied to other standards than the Telcordia SR-332 standard mentioned above with minor adaptations to the particular equations and approaches used in the respective standard.

For the above equations, for a precise calculation the temperature and relevant parameter a (power, current, voltage etc.) has to be known for each component. In embodiments discussed herein, a simplification is made in that these parameters are measured on a circuit level, and assumptions are made for the calculation of the parameters for the components. For example, in embodiments the following simplifications are used:
All components experience the same temperature, e.g. the system or environmental temperature with respect to the same reference temperature independent of the component i as:

$$\frac{1}{{T}_{0}} - \frac{1}{{T}_{env}}$$

Subsets of components share the same α parameter, i.e. have the same relationship to a specific operating condition, for example voltage, current, power etc. For example, all components for which α corresponds to a voltage may form a subset, all components for which α corresponds to the electrical power are in the same subset, etc.
Subsets of components share the same Eₐ_{ᵢ}, i.e. the same activation energy.
To arrive at the subsets, components may be clustered in subsets which share similarity, for example component type (for example all resistor), stress vector (for example all components at an input stage which are subjected to a same input voltage or current) or based on functional components within the system, for example a filter component like an output filter, or mixtures of the above approaches.

To reduce the dimensionality of the complete calculation, some of the above simplifications must be applied simultaneously. For example, the temperature simplification mentioned above (all components experience the same temperature) only reduces the computational complexity of the above equation if the activation energies are also assumed to be the same at least for subsets of components. It should be noted that in some cases, depending on the circuit the subset may also include all components.

Depending on the size of the circuit, applying one or more of the above assumptions and simplifications the calculation may be implemented in a controller as shown in FIG. 4 (controller 42) or calculation logic 31 without requiring a very high computing power, which facilitates an implementation within the circuit in some embodiments.

As mentioned, other standards use similar definitions for reliability prediction parameters and values, and the above approach may be used as well. For example, in MIL-HDBK-217F a part failure rate, essentially corresponding to

$$( {λ}_{{comp}_{i}}^{acc} )$$

above, is defined as λₚ=λ_{b}π_{T}π_{A}π_{R}π_{S}π_{C}π_{Q}π_{E}
where:
λ_{b} is the base failure rate usually expressed by a model relating the influence of electrical and temperature stresses on the part, i.e. component, and the 7 values modify the base failure rate for different categories of influence, in particular the following ones are used: π_{E} environment factor, π_{T} temperature factor,
π_{A} application factor,
π_{R} power rating factor,
π_{S} electrical stress factor,
π_{C} construction factor,
π_{Q} quality factor, and
π_{L} learning factor. Details can be taken from the corresponding standard.

For most of the models, some basic reliability description or base failure rate is needed, for example λ_{comp}_{ᵢ} in case of the Telcordia model or base failure rate λ_{b} above. A simple approach (described in the Telcordia SR-332) is to obtain the FIT (Failure-In-Time) parameter from the component data sheet.

The advantage of using FIT rates in some embodiments is that they are easily accessible for circuit designers from component manufacturers, but they do not account for derating depending on operation parameters, also referred to as mission profile dependent derating, which in equation (6) is accounted for by vector S and which will be further explained below.

The proposed reliability prediction procedure is not limited to the discussed procedures from reliability standards as mentioned above, but also integration of/combination with reliability prediction methods beyond the scope of reliability handbooks may be covered by the proposed approach.

As an example, component specific lifetime models designed by the component or device manufacturer can be used. Such models describe the typical lifetime of a component or device under operation considering component specific effects such as deterministic wear-out effects.

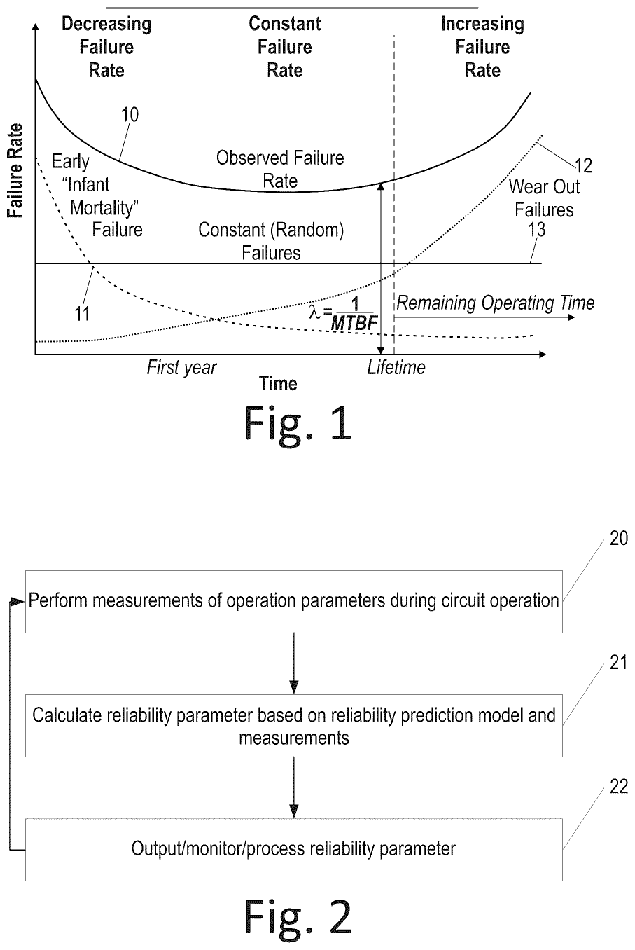

A common approach to modeling reliability beyond the scope of reliability handbooks incorporates the Weibull distribution, especially for the phases of Wear Out Failures in curve 12 or Early “Infant Mortality” Failures in curve 11 in FIG. 1. Depending on the specific definition of the Weibull distribution used, up to three different parameters are specified to describe the probability density function modeling the reliability respectively lifetime of components. Usually, those parameters are denoted as scale parameter β (or characteristic life), η shape parameter (or slope) and location parameter γ (or failure free life). Depending on a specific choice of those parameters, different phases can be modeled, as an example the Wear Out Failures in curve 12 or Early “Infant Mortality” Failures in curve 11 in FIG. 1. The following formula denotes the 3-parameter (β, η, γ) Weibull probability density function:

$$f ( t ) = \frac{β}{η} {( \frac{t - γ}{η} )}^{β - 1} {e}^{- {( \frac{t - γ}{η} )}^{β}} for t \geq γ , else 0. \qquad ( 7 )$$

Depending on the specific literature, other definitions are common as well. Hence, the above formula and the following description shall be an example illustrating one potential approach, but are not to be construed as limiting.

In order to create a lifetime model, as an example, component manufacturers execute lifetime acceleration tests. At the end of those tests, the static parameter β, η, and γ can be calculated/modeled from the data. Using the Weibull distribution, reliability prediction parameters can be calculated for the specific component, as an example through a cumulated distribution function describing the probability of failure within a specific time period.

In the discussed approach, the static parameters model, as an example, the respective acceleration tests, temperature dependent effects, and deterministic wear-out effects of the component while it operates the time t.

Integrating the above formula into the approach described above can be done analog to the calculation method described above and below by separating a static part (parameters β, η, and γ) in the formula from a dynamic part (in the above example the operation time t). In this approach, the calculation method would then not obtain λ, but directly, as an example, probability of failure as a reliability prediction parameter of the respective component.

Compared to some conventional solutions in embodiments the reliability prediction model is used in a calculation logic (e.g. controller) within the electronic circuit together with the real measured operation parameters to calculate a reliability prediction parameter in situ.

As mentioned, in embodiments the determination of the reliability prediction parameter may rely on operation parameters measured “globally” by the electronic circuit, i.e. circuit-level parameters, and not individually for each component. From these, operation parameters for the individual components may be estimated. This will be explained in the following in more detail.

In general, an electronic circuit like a power supply has circuit level operation parameters P_{sys} like system or ambient temperature, input voltage for example from a power grid, output voltage, input current, output current or also voltages and currents within the circuit. The circuit-level operation parameters P_{sys} may be written as a column vector of dimension K×1, with K the number of circuit-level operation parameters, according to

$${P}_{sys} = ( \begin{matrix}{T}_{ambient} \\ {V}_{input} \\ {V}_{output} \\ {I}_{input} \\ {I}_{output} \\ ⋮ \\ {P}_{K}\end{matrix} ) \qquad ( 8 )$$

In the above equation (6) where the μᵢ are calculated S is a vector defining the operation parameters of all N components of the electronic circuit, i.e. Tᵢ and αᵢ. To distinguish from the above P_{sys}, this vector will also be referred to as P_{comp} below and may be split into a static part P_{compstat} and a dynamic part P_{compDyn} according to

$${P}_{comp} := S = ( \begin{matrix}1 \\ \frac{1}{{T}_{{1}_{0}}} - \frac{1}{{T}_{1}} \\ ⋮ \\ \frac{1}{{T}_{{N}_{0}}} - \frac{1}{{T}_{N}} \\ {α}_{1} - {α}_{{1}_{0}} \\ ⋮ \\ {α}_{N} - {α}_{{N}_{0}}\end{matrix} ) \text{=:} {P}_{compStat} + {P}_{compDyn} = ( \begin{matrix}1 \\ \frac{1}{{T}_{{1}_{0}}} \\ ⋮ \\ \frac{1}{{T}_{{N}_{0}}} \\ - {α}_{{1}_{0}} \\ ⋮ \\ - {α}_{{N}_{0}}\end{matrix} ) + ( \begin{matrix}0 \\ - \frac{1}{{T}_{1}} \\ ⋮ \\ - \frac{1}{{T}_{N}} \\ {α}_{1} \\ ⋮ \\ {α}_{N}\end{matrix} ) \qquad ( 9 )$$

In conventional reliability assessment approaches, the individual parameters Tᵢ or αᵢ were measured for example using digital oscilloscopes and sensors connected directly to the component for ex-situ reliability assessment. However, measuring the temperature and electrical parameters for all components in real time and/or in situ usually is not feasible for larger circuits. However, through such ex-situ measurements and/or simulations of the electronic circuit, it is possible to obtain an estimation of a relationship between individual component parameters and parameters on circuit level. For example, in case of a power converter as shown in FIG. 4, in a control loop controller 42 measures circuit level operating conditions like voltage and current at input and output of the power converter ambient temperature or temperature of the power converter.

The general length of the vector P_{comp} is 2N+1 in this approach based on Telcordia SR-332, where N is the number components in the circuit. In other approaches, the length may be different. Matrices D_{static} and D_{dynamic} correlate the component operation parameters to the circuit level operation parameters, also referred to as system parameters herein, according to

$${P}_{comp} = {P}_{compStat} + {P}_{compDyn} := {D}_{static} {P}_{sys} + ( \begin{matrix}1 \\ 0 \\ ⋮ \\ 0 \\ 0 \\ ⋮ \\ 0\end{matrix} ) + {D}_{dynamic} {P}_{sys} \qquad ( 10 )$$

The respective matrices D_{static} and D_{dynamic} can have the following shape, with matrix entries l for D_{static} and k for D_{dynamic} according to

$$( \begin{matrix}1 \\ \frac{1}{{T}_{{1}_{0}}} \\ ⋮ \\ \frac{1}{{T}_{{N}_{0}}} \\ - {α}_{{1}_{0}} \\ ⋮ \\ - {α}_{{N}_{0}}\end{matrix} ) = ( \begin{matrix}0 & … & 0 \\ {l}_{2 , 1} & … & {l}_{2 , K} \\ ⋮ & … & ⋮ \\ {l}_{N + 1 , 1} & … & ⋮ \\ {l}_{N + 2 , 1} & … & ⋮ \\ ⋮ & … & ⋮ \\ {l}_{2 N + 1 , 1} & … & {l}_{2 N + 1 , K}\end{matrix} ) ( \begin{matrix}{T}_{ambient} \\ {V}_{input} \\ {V}_{output} \\ {I}_{input} \\ {I}_{output} \\ ⋮ \\ {P}_{K}\end{matrix} ) + ( \begin{matrix}1 \\ 0 \\ ⋮ \\ 0 \\ 0 \\ ⋮ \\ 0\end{matrix} ) \text{=:} {D}_{static} {P}_{sys} + ( \begin{matrix}1 \\ 0 \\ ⋮ \\ 0 \\ 0 \\ ⋮ \\ 0\end{matrix} ) \qquad ( 11 a )$$

$$( \begin{matrix}0 \\ - \frac{1}{{T}_{1}} \\ ⋮ \\ - \frac{1}{{T}_{N}} \\ {α}_{1} \\ ⋮ \\ {α}_{N}\end{matrix} ) = ( \begin{matrix}0 & … & 0 \\ {k}_{2 , 1} & … & {k}_{2 , K} \\ ⋮ & … & ⋮ \\ {k}_{N + 1 , 1} & … & ⋮ \\ {k}_{N + 2 , 1} & … & ⋮ \\ ⋮ & … & ⋮ \\ {k}_{2 N + 1 , 1} & … & {k}_{2 N + 1 , K}\end{matrix} ) ( \begin{matrix}{T}_{ambient} \\ {V}_{input} \\ {V}_{output} \\ {I}_{input} \\ {I}_{output} \\ ⋮ \\ {P}_{K}\end{matrix} ) \text{=:} {D}_{static} {P}_{sys} \qquad ( 11 b )$$

Therefore, a matrix for the static components D_{static} and for the dynamic components D_{dynamic} may be used. It should be noted that through simple matrix arithmetic these can be also combined to a single matrix, such that the writing as two matrices is only for better understanding, and the way the calculations are written down is not to be construed as limiting in any way. The parameters l and k, that is the respective matrix entries, are correlating the circuit level operation parameters to the components specific parameters. The parameters l and k may be static or may themselves be described as a function, for example k=f(x), so that they have an explicit dependency like being dependent on the actual temperature in a non-linear way. One simple example is a resistive divider with two resistors R₁ and R₂ for an input voltage as system parameter, out of which the respective voltage at R₁ and R₂ can be calculated by R₂/R₁ through k=R₂/(R₁+R₂), i.e. V_{R2}=kVᵢₙ, where V_{R2} is the voltage at resistor R₂ and Vᵢₙₚᵤₜ is the input voltage.

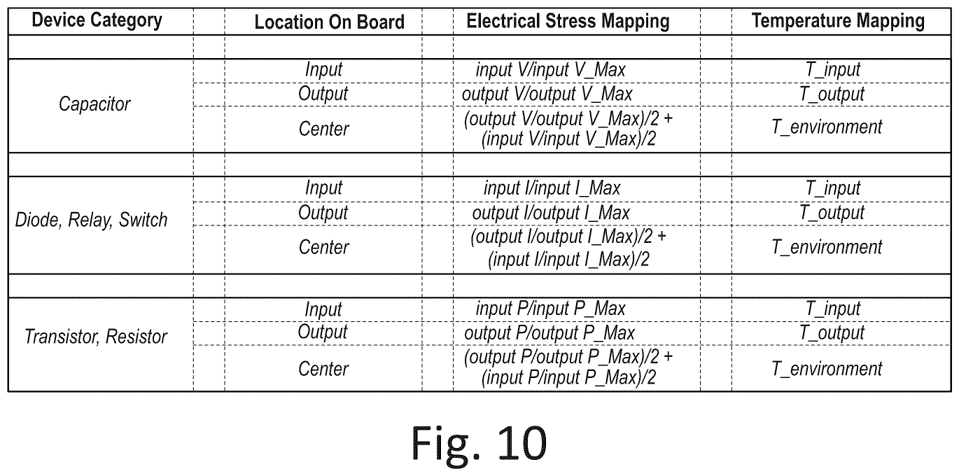

FIG. 10 illustrates a simple example how relationships between operation parameters on circuit level (input voltage input V, output voltage output V, input current input I, output current output I, input power input P, output power output P, and maximum values thereof which are respectively denoted by appending _Max in FIG. 10) to different capacitors, diodes, relays, switches, transistors or resistors at different locations on a printed circuit board (input side, output side, center) may be mapped. Additionally, a temperature T_input at the input side, a temperature T output on the output side and an ambient temperature T environment is used. Here, for the D_{static}P_{sys} and D_{dynamic}P_{sys} as mentioned above it may be assumed that for example components on the input side have approximately the same temperature T_input and for example input capacitors essentially see the input voltage input V. In FIG. 10, Device Category refers to a categorization of the components of the electric circuit based on similarity of device types, e.g. all resistors or all capacitors, Location On Board refers to the physical location on the printed circuit board (PCB) of the electronic circuit, e.g. all components on the input side, output side or center of the board (between input and output). Electrical Stress Mapping refers to similarities of the components in electrical stress parameters p of the respective acceleration factor (and subsequently α and γ), where the measured values (power, voltage or current) in the example are shown are divided by their respective maximum values. Temperature Mapping refers to similarities of the components in operation temperature T of the respective acceleration factor, e.g. the approximate temperature on the input side.

The matrix operations or corresponding functions can be executed on a controller or other calculation logic like calculation logic 31 or controller 42 embedded in the respective electronic circuit. The parameters themselves, i.e. l and k as mentioned above can be derived by measurements for example on a prototype circuit for example infrared thermal images and/or from calculation methods based on the design, for example SPICE simulations, finite element method (FEM) simulations like provided by Ansys Icepack or the like.

As already mentioned above, depending on the number of components of the electronic circuit and the computing power available for example in an embedded controller, simplifications and compressions of the calculation methods may be used. In particular, the parameters l and k are determined in advance.

Taking a power converter as shown in FIG. 4 as an example, by a SPICE simulation involves setting up a complete simulation of the power converter, running it in steady state for a specific operating point, and calculating the transfer function between a selective circuit level operation parameter and a component operation parameter. This transfer function in this approach is then saved in the respective parameters l and k.

For a temperature distribution a finite element method simulation or computer aided design (CAD) derived models may be used to simulate a complete electronic circuit, for example provided on a printed circuit board (PCB), at a specific operating point. Then, using the simulations a transfer function may be calculated or approximated to determine the temperature at any point of the electronic circuit based on a temperature measurement point. From this, then the temperature at the component may be linked to a specific measurement temperature or ambient temperature by modelling the respective relationship in a function.

As an alternative or additionally thereto, infrared thermal imaging may be used to create a model that predicts the temperature at a specific point of the electronic circuit based on the system operation parameters. This is achieved by operating the electronic circuit at different operating points, taking infrared thermal images, and using image recognition, for example based on an artificial intelligence (AI) model, to create a trained model for predicting the temperature. The model can then be executed on the embedded calculation logic of the circuit itself or used to construct the above calculation functions.

To improve the accuracy, also additional measurement points and historical data may be used to improve the accuracy of the parameters l and k and other functions used correspondingly.

The system operation parameters are directly available to the calculation logic, and additional external measurement points such as vibration measurements may be used. Historical data for example from returned power supplies (for example returned as defective) with logging memory can be utilized to improve the reliability prediction models, considering system degradation over time.

The above approach may be easily extended to using additional parameters, as it is not limited to any specific parameters or number thereof.

In summary, in the approach above calculation approaches based on standards, also referred to as reliability handbooks, are modified by separating a static part based on the static component parameters from dynamic operation parameters and linking them to system operation parameters. In some embodiments, additional steps are taken for a repeated calculation of the reliability prediction parameter λ_{sys} over time.

One reliability prediction parameter of interest further to λ_{sys} discussed above and driveable therefrom is the mean time between failures, MTBF, which is defined as the expected random variable time t_{MTBF} indicating a time between subsequent failures of an electronic circuit (if the electronic circuit can be repaired after each failure). Otherwise, the term used is usually MTTF, mean time to failure, but a similar approach as explained below for MTBF applies.

The MTBF may be calculated according to

$$MTBF := {t}_{MTBF} = {\int }_{0}^{∞} {tf}_{{t}_{MTBF}} ( t ) dt , \qquad ( 12 )$$

where fₜ_{_{MTBF}}(t) is a respective probability density function that correlates the time t with the probability that the failure occurs. A constant failure rate as outlined earlier with respect to FIG. 1 of

$$λ = \frac{1}{MTBF}$$

implies that fₜ_{_{MTBF}}(t) has an exponential distribution with parameter λ. As an exponential distribution with parameter λ (e.g. λ_{sys}), fₜ_{_{MTBF}}(t) can be modelled as a probability density function of an exponential distribution according to

$${f}_{{t}_{MTBF}} ( t ) = λ {e}^{- λ t} for t > 0 , else 0. \qquad ( 13 )$$

The probability that the electronic circuit has failed, i.e. the failure event has occurred, from 0 until a time t may be modelled through the cumulative distribution function (CDF) by:

$${F}_{CDF} ( t , λ ) = 1 - {e}^{- λ t} for t \geq 0 , else 0. \qquad ( 14 )$$

In some embodiments the measurements of the circuit level operation parameters are performed in discrete time steps tᵢ, in regular intervals Δt=tᵢ₊₁−tᵢ, which corresponds to a fixed sampling rate fₛₐₘₚₗₑ. In other embodiments, irregular intervals may be used, corresponding to a varying sampling rate.

$${λ}_{sys}^{i}$$

is the reliability prediction parameter λ_{sys} above at sampling point tᵢ, calculated e.g. by equations (2) and (6) with (10) and (11). The

$${λ}_{sys}^{i}$$

may vary between different time steps as they are according to the above equations depending on the actual operating conditions (operation parameters) assigned to the respective time point tᵢ, i.e. sampled at these times.

In some embodiments, the cumulative distribution function is used to combine the

$${λ}_{sys}^{i}$$

as the cumulative distribution function allows to model the probability that an event took place between two points in time, i.e. the probability between two arbitrary points in time t₁ and t₂ may be obtained by subtracting the respective cumulative distribution functions from each other. The cumulative distribution functions from the different times tᵢ may be combined in the following way:

$${F}_{CDF}^{t + Δ t} = {F}_{CDF}^{t} + ( 1 - {F}_{CDF}^{t} ) ( {F}_{CDF} ( Δ t , {λ}_{t + Δ t} ) ) \qquad ( 15 )$$

In this way, the cumulative distribution function after a further time step Δt may be calculated based on the cumulative distribution function before this time step Δt (for example a time tᵢ). The above formula can be applied recursively to construct the value of the CDF function from any point in time onwards, for example from start of measurement until the current time. The different elements of these equations are as follows:

$${F}_{CDF}^{t + Δ t}$$

The new joined value of the CDF function describing the failure probability of the device after time t+Δt.
F_{CDF}^{t}
Current value of the joined CDF function at t.

$$( 1 - {F}_{CDF}^{t} )$$

Probability that a device survives until t.
F_{CDF}(Δt,λ_{t+Δt})
Value of the CDF function for Δt with newly calculated lambda Δ_{t+Δt} for the respective time period calculated using formula (14). Δ_{t+Δt} is the λ_{sys} at the time t+Δt.

From the respective CDF values, a

$${λ}_{av}^{t} and {λ}_{av}^{t + Δ t}$$

describing an average λ of past time periods can be obtained. This

$${λ}_{av}^{t} and {λ}_{av}^{t + Δ t}$$

can be explicitly calculated by solving equation (14) for λ and using the current time t or t+Δt and the respective CDF value

$${F}_{CDF}^{t} or {F}_{CDF}^{t + Δ t} .$$

This is illustrated in FIG. 5. In the example of FIG. 5, sampling points t0, t1, t2 and t3 are used. In this example, the sampling is performed in irregular intervals, i.e. Δt is not constant, but the same equation as discussed above apply.

FIG. 5 shows the cumulative distribution function over time. Based on the above equations, a piecewise continuous function results, where a curve 51 corresponds to the CDF for the first time interval, 52 for the second time interval and 53 for the third time interval. Curve 50 corresponds to an average overall CDF, which can be calculated as outlined earlier by solving equation (14) for λ and using time t3 and the y-value at the end of this time interval.

In this way, continuously the reliability prediction parameter λ_{sys} is calculated and used to update the cumulative distribution function (which may also be seen as a reliability prediction parameter).

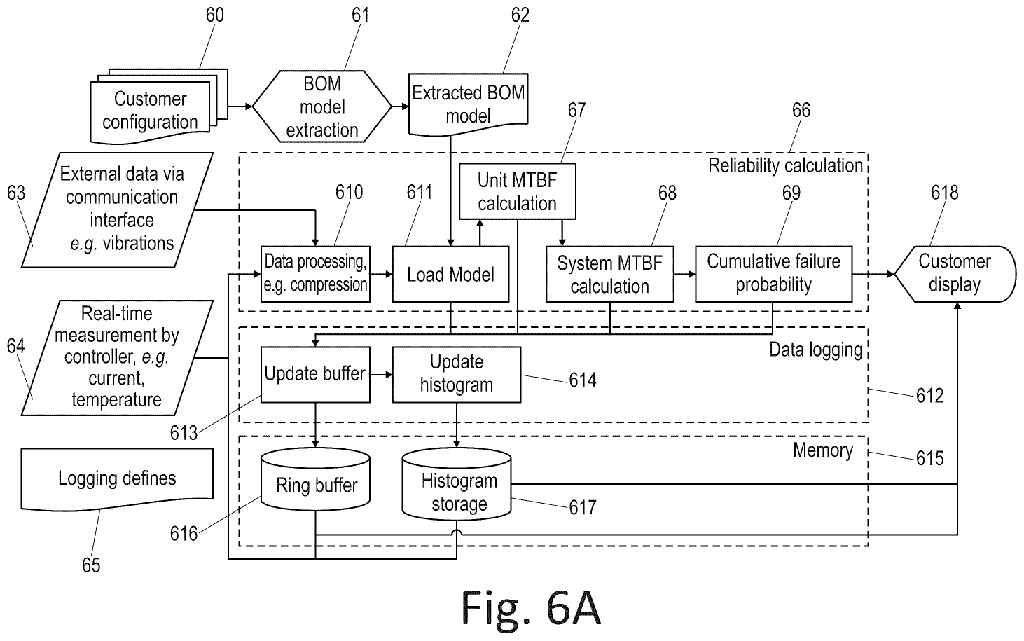

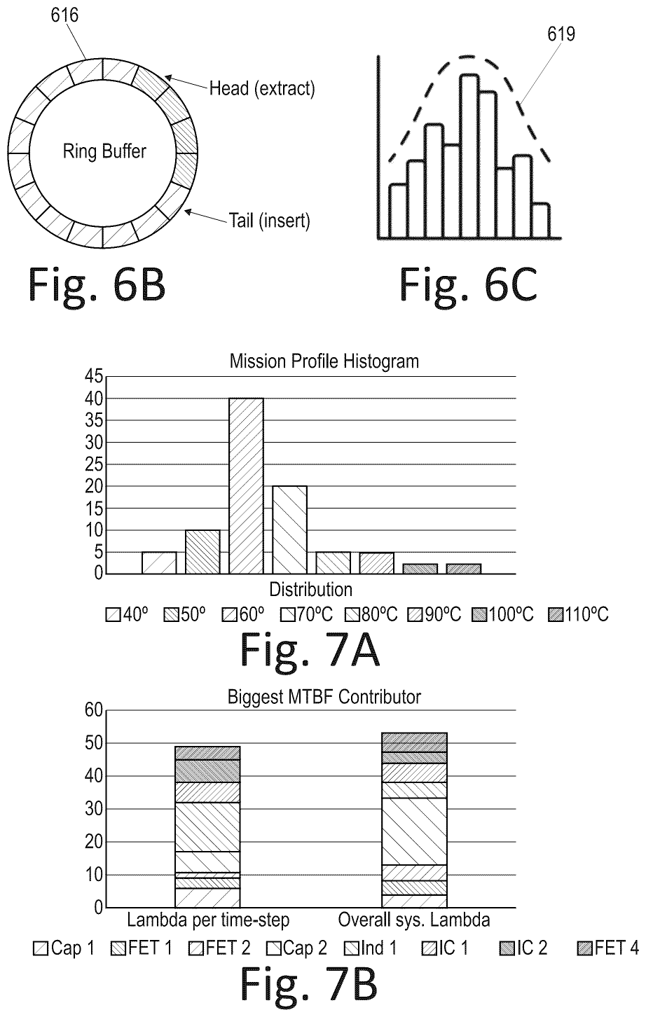

FIG. 6 shows a functional diagram illustrating some embodiments using the methodology described above in detail.

In addition to calculating reliability prediction parameters as discussed above, FIG. 5 also describes possibilities for logging the reliability data and other data associated therewith for information, monitoring or analysis purposes, as will be described further below in more detail.

In FIG. 6, blocks 66, 612 and 615 represent the functionality of a calculation logic like calculation logic 31 of FIG. 3 or controller 42 of FIG. 4.

Based on a customer configuration 60 of an electronic circuit, a BOM model extraction 61 is performed to obtain a BOM model 62, i.e. a model of the components as defined for example in the above equations. This model 62 is provided to reliability calculation block 66. Furthermore, reliability calculation block 66 receives real-time measurements, for example current, voltage or temperature measurements 64 which may be performed by the controller performing the reliability calculations. Furthermore, external data 63 may be provided to block 66 via a communication interface of the electronic circuit, for example data regarding vibrations, humidity or other environmental data.

The measurement data may be processed, for example compressed of filtered, at block 610 and together with the external data may be used to provide a load model, together with the BOM model 62. The load model corresponds to the vector P_{comp} of the above equations, which is obtained based on the parameters P_{sys}, i.e. the real-time measurements at 64 and optionally the external data 63. Based on the model, then in block 67 the individual reliability values for the components or component subsets may be calculated (i.e. μᵢ or

$${λ}_{{comp}_{i}}^{acc} ) ,$$

or as inverse thereof the MTBF for the individual components or subsets, and in block 68 the reliability prediction parameter for the circuit, λ_{sys} may be calculated. In block 69, based thereon a cumulative failure probability will be calculated, for example using the CDF calculations explained above, and for example displayed to the customer of the circuit on a display 618.

Furthermore, data may be logged and stored in memory block 615 by data logging block 612 based on logging defines 65 which describe which data is to be logged. In particular, the reliability prediction parameters for the circuit and/or for the individual components may be stored in a ring buffer 616 in block 614, and/or histograms 617 may be updated by block 614.

The processed measurements of block 610 may also be logged in ring buffer 616. A ring buffer 616, more precisely shown in FIG. 6B, may in particular be used if only limited storage is available on the electronic circuit. In the ring buffer, all the parameters, including operation parameters and reliability prediction parameters, may be stored together with a time stamp corresponding to the above mentioned time tᵢ at which the operation parameters are sampled. This may help later for example during an analysis of a failure to know which operating conditions occurred simultaneously to or preceding the failure. As new data is written into the ring buffer at the head, and older data at the tail may be discarded.

Furthermore, a histogram for the operation parameters and/or for the reliability prediction parameter values for the electronic circuit (λ_{sys}) or for the individual components may be stored in a histogram storage 617 and updated with each sampling time. Such an example histogram 619 is shown in FIG. 6C. In the histogram the time information is lost, but information about which conditions and/or reliability prediction parameters occurred how often may be preserved even if discarded from the ring buffer. The histogram may quantize the full range of a corresponding operating conditions or parameters are quantized. For example, for a voltage like Vᵢₙₚᵤₜ or Voutput above, the full range may be from 0-100V with a resolution of 1V, corresponding to 100 bins of the histogram. The number of bins, i.e. the resolution, may be defined for each parameter to be logged.

Parameters which determine the logging include size of the allocated memory for the ring buffer and histogram storage, the data which is stored, i.e. reliability prediction parameters, raw data (measured operation parameters, compressed data to save memory storage, register data and the like, the number and resolution of the bins for the histograms, and possible additional parameters).

The memories used may be for example internal flash memory of a controller or external non-volatile or volatile memory such as EEPROMs, NOR/NAND Flash, FRAMs, etc., or also external flash memory. Furthermore, the ring buffer may be read out regularly by an external entity, for example controller of a system where the electronic circuit is incorporated or a monitoring device, for continuous monitoring.

The calculation of the reliability parameter may then additionally or alternatively be performed based on the measurements stored in the ring buffer and/or based on the histogram(s). For example, as mentioned a calculation logic used for calculation of the reliability parameter may also employed for other purposes like controller 42 of FIG. 4, which controls operation of power converter 40. In such a case, calculation of the reliability parameter may be performed based on the stored measurements during times when the calculation logic has processing power to spare, for example when power converter 40 is idle or does not require high processing power for control, and may be postponed to such times when all processing power of the calculation logic is needed for other purposes. Therefore, while the calculation may be performed for each measurement, this does not imply that the calculation has to happen immediately, but may also performed based on stored measurement data later.

Next, various possible uses for the reliabilities and/or data stored in the histogram and/or logged data will be discussed.

One possible use for histograms is to determine the main contributors to failures and component stress. For example, the already mentioned histograms for operation parameters can be used to estimate the stresses for an individual component or subset, using the parameters l and k above. As an example, FIG. 7A shows a histogram for a temperature distribution. It can be seen from such a histogram that most of the operation takes place around 70-80° C., but in some instances a heating up to 110° C. occurs. Analyzing the temperature distribution over the components or subsets can help understand the temperature induced stress to the component and therefore, its contribution to the system.

The reliability prediction parameters for the individual components, e.g.

$${λ}_{{comp}_{i}}^{acc} ,$$

or for the electronic circuit, e.g. λ_{sys} or parameters derived therefrom via the CDF may also be used as an indication for the overall stress experienced by the circuit. By displaying the reliability prediction parameter in a histogram, a user can read out the accumulated stress of an electronic circuit without knowing exactly what electrical stresses and temperatures have been applied.

Furthermore, as shown in FIG. 7B the biggest contributors to failures, i.e. to the mean time between failures or other reliability prediction parameter, may be identified. On the left side of FIG. 7B, for example components (capacitor 1, field effect transistor (FET) 1, FET2, inductor (Ind) 1, integrated circuit (IC) 1, IC2, FET4, contributions per a single time step are shown. As can be seen, in this example the inductor 1 has the greatest value. However, the biggest contribution to the overall system λ_{sys}, shown on the right side of FIG. 7B, is from capacitor 2 (greatest λ). As every component has a base failure rate, the failure rate changes with the operating conditions. Therefore, based on the logged information, two different analyses can be performed.

The most stressed component may be obtained by analysing the relative differences between the base failure rate (e.g. λ_{comp}_{ᵢ}) to the effective failure rate. For example if the base failure rate grows by a factor of for example 5, this particular component will be relatively more stressed than a component which failure rate grows by a factor of 3.

However, even a more stressed component (for example inductor 1 on the left side of FIG. 7B) may contribute less to the overall λ_{sys} of the electronic circuit than a less stressed component. Therefore, an analysis can be done which component contributes most to the overall circuit λ_{sys} as shown on the right side of FIG. 7B. This may be done for every timestamp (tᵢ) or can be done relatively compared to the baseline reliability. This may for example enable a designer of the electronic circuit to decide which parameters to improve as the biggest contributor to the MTBF in the field is also likely to fail. Therefore, for example, in FIG. 7B improving capacitor 2 may have the largest impact of improving the reliability of the electronic circuit.

Another use of the reliability prediction parameter is load balancing in case several circuits of the same types are used in parallel. For example, in some applications a plurality of power converters like the one shown in FIG. 4 are used in parallel. Here, a power management controller 45 may perform load balancing based on the reliability prediction parameters for the individual power converters obtained. If the failure probability of one of the power converters rises strongly, this power converter may be assigned less load than other power converters to reduce its stress, to ensure a statistically equal lifetime of all power converters in a system, as already mentioned above.

Furthermore, the determination of the failure probability, for example in form of the cumulative distribution functions as explained above, may be used to more realistically assess the failure probability than based on information obtained for example by ex situ reliability tests performed by a manufacturer.

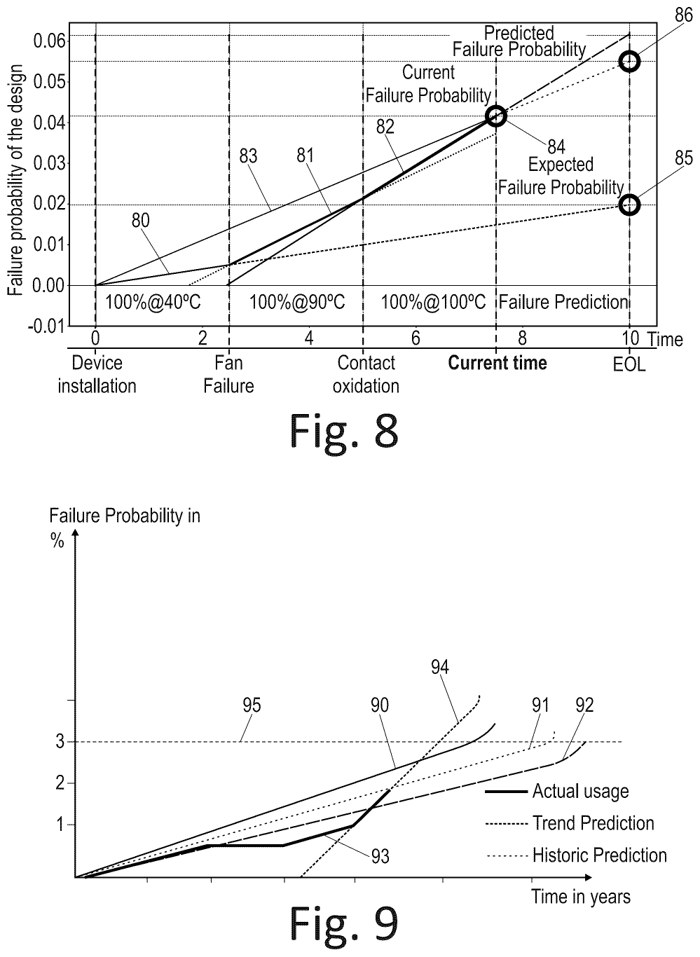

This will be explained referring to FIG. 8. FIG. 8 shows the failure probability over time. A predicted behaviour is shown by curve 80, which is extended to an end of life (EOL) to give an expected failure probability at the end of life designated 85. Until a point in time where for example a fan cooling the circuit fails, the actual behaviour corresponds to the expected behaviour, i.e. curve 80. With this fan failure, the temperature rises (in the example shown from 40° C. to 90° C.), leading to an increase of failure probability as indicated by curve 81. Later in time, contact oxidation occurs, which leads to another rise in temperature to 100° C. and a steeper increase of the failure probability, as indicated by curve 82, leading to a current failure probability at a current time designated 84. A curve 83 averages curves 80-82 (similar to curve 50 of FIG. 5), leading to a predicted failure probability designated 86 at end of life, which is considerably higher than the expected failure probability at 85. Therefore, this electronic circuit may be taken out of service earlier than given by the expected lifetime.

A more detailed example for health assessment is shown in FIG. 9. A curve 93 shows the failure probability determined as described herein, corresponding to the actual usage, and a curve 94 is an extrapolation of the end of curve 93, i.e. a prediction based on the trend. A curve 91 represents a historic prediction, for example an expected behaviour based on past uses of this circuit. A curve 92 illustrates an average case, and a curve 90 illustrates a worst-case reliability estimation. With the extrapolation (curve 94 and curve 91) a point in time can be calculated in which the failure probability crosses a predefined threshold. Curve 94 is an extrapolation based on the slope of the last (most recent) segment of curve 93, while curve 91 is an extrapolation using the current value of curve 93 (last value shown in the graph), such that curve 91 goes through the origin and the last value of curve 93, which is a kind of averaging. Other extrapolations may also be used, for example other kind of averaging (like a line fitted to curve 93 using e.g. a least square method), or an averaging that only takes a certain part of curve 93 into account, e.g. the last xx years, months, etc. The time difference between the threshold and the current failure probability value could be linked to a traffic light logic (i.e. a logic outputting red, yellow or green depending on the health of the circuit, green being best and red being worst) or as a remaining lifetime, for example according to one of the following logic approaches

timeOverThreshold = operationalTime − projectedTimeOfThresholdCrossing
if( timeOverThreshold < −3 month) Health = green
if( −3 month < timeOverThreshod < 3 month) Health = yellow
if(timeOverThreshold > 3 month) Health = red
Or:
remainingLife = projectedTimeOfThresholdCrossing − operationalTime

In the above pseudo code, operationalTime is the current time value, the projectedTimeOfThresholdCrossing is the time where the extrapolation (94 or 91) crosses a threshold (for example curve 90 or a fixed threshold, e.g. 3% failure probability as represented by curve 95), and health is a status. Of course, parameters like “three months” as a time variable etc. serve only as examples.

In other embodiments, the actual failure probability may be compared to an average probability or to a worst case probability, according to the following pseudo code

Health = green : failProp_{actual} < failProp_{average}
Health = yellow : failProp_{average} < failProp_{actual} < failProp_{worstCase}
Health = red : failProp_{worstCase} < failProp_{actual}

Here failProp_{actual} is the calculated current failure probability, for example according to curve 93 or extrapolation curves 91, 94, failProp_{average} may correspond to the current value of curve 92, and failPropworst_{case} may correspond to the current value of curve 90.

Some embodiments are defined by the following examples:

Example 1. A method, comprising:
repeatedly performing a measurement of a plurality of operation parameters of an electronic circuit during operation of the electronic circuit,
for each measurement calculating, by the electronic circuit, a reliability prediction parameter of the electronic circuit based on the measurements and a reliability prediction model of the electronic circuit.

Example 2. The method of example 1, wherein the reliability prediction model is based on a bill of materials of the electronic circuit.

Example 3. The method of example 1 or 2, wherein the reliability prediction model is a standard model or derived thereof.

Example 4. The method of example 3, wherein the reliability prediction model is according to one of Telcordia SR-332, Mil-HDBK-217, ANSI/VITA 51.1, NPRD/EPRD, IEC 61709, Siemens SN 29500, IEC-TR-62380, FIDES, 217Plus or GJB/Z 299C and GJB/Z 299B.

Example 5. The method of any one of examples 1 to 4, wherein the model calculates individual reliability prediction parameters for different components of the electronic circuit and combines the individual reliability prediction parameters to the reliability prediction parameter of the electronic circuit.

Example 6. The method of example 5, wherein calculating the individual reliability prediction parameters comprises estimating individual operation parameters for the components based on the operation parameters of the electronic circuit, and calculating the individual reliability prediction parameters based on the individual operation parameters.

Example 7. The method of example 5 or 6, comprising grouping the components to subsets, and, for the calculation of the individual reliability prediction parameters, assuming similar operation parameters and/or further parameters for the components of each subset.

Example 8. The method of any one of examples 5 to 7, further comprising outputting information about contributions of the different components to the reliability prediction parameter of the electronic circuit.

Example 9. The method of any one of examples 1 to 8, wherein the method is implemented in a controller of the electronic circuit.

Example 10. The method of any one of examples 1 to 9, wherein the electronic circuit comprises a power converter.

Example 11. The method of any one of examples 1 to 10, wherein the method further comprises, for each measurement, updating a cumulative distribution function based on the reliability prediction parameter.

Example 12. The method example 11, further comprising outputting a health status based on the updated cumulative distribution function and an expected cumulative distribution function.

Example 13. The method of any one of examples 1 to 12, wherein the method comprises storing the measurements, wherein the calculating for each measurement is at least for some measurements performed on the stored measurements.

Example 14. The method of example 13, wherein the storing of the measurements comprises storing of the measurements as histograms.

Example 15. The method of any one of examples 1 to 14, wherein the method further comprises controlling the electronic circuit based on the reliability prediction parameter.

Example 16. An electronic circuit, comprising:
measurement circuitry configured to measure a plurality of operation parameters of the electronic circuit, and
a calculation logic configured to repeatedly calculate a reliability prediction parameter for the electronic circuit based on a respective measurement of the plurality of operation parameters and a reliability prediction model of the electronic circuit.

Example 17. The electronic circuit of example 16, wherein the calculation logic is configured to perform the method of any one of examples 1 to 13.

Example 18. The electronic circuit of example 16 or 17, wherein the reliability prediction model is based on a bill of materials of the electronic circuit.

Example 19. The electronic circuit of any one of examples 16 to 18, wherein the reliability prediction model is a standard model or derived thereof.

Example 20. The electronic circuit of example 19, wherein the reliability prediction model is according to one of Telcordia SR-332, Mil-HDBK-217, ANSI/VITA 51.1, NPRD/EPRD, IEC 61709, Siemens SN 29500, IEC-TR-62380, FIDES, 217Plus or GJB/Z 299C and GJB/Z 299B.

Example 21. The electronic circuit of any one of examples 16 to 20, wherein the model calculates individual reliability prediction parameters for different components of the electronic circuit and combines the individual reliability prediction parameters to the reliability prediction parameter of the electronic circuit.

Example 22. The electronic circuit of example 21, wherein the calculation logic, for calculating the individual reliability prediction parameters, is configured to estimate individual operation parameters for the components based on the operation parameters of the electronic circuit, and calculating the individual reliability prediction parameters based on the individual operation parameters.

Example 23. The electronic circuit of example 21 or 22, wherein the calculation logic is configured to group the components to subsets, and, for the calculation of the individual reliability prediction parameters, assume similar operation parameters and/or further parameters for the components of each subset.

Example 24. The electronic circuit of any one of examples 21 to 23, wherein the electronic circuit is configured to output information about contributions of the different components to the reliability prediction parameter of the electronic circuit.

Example 25. The electronic circuit of any one of examples 16 to 24, wherein the calculation logic is implemented by a controller of the electronic circuit.

Example 26. The electronic circuit of any one of examples 16 to 25, wherein the electronic circuit comprises a power converter.

Example 27. The electronic circuit of any one of examples 16 to 26, wherein the calculation logic is configured to, for each measurement, update a cumulative distribution function based on the reliability prediction parameter.

Example 28. The electronic circuit of example 27, further configured to output a health status based on the updated cumulative distribution function and an expected cumulative distribution function.

Example 29. The electronic circuit of any one of examples 16 to 28, wherein the electronic circuit comprises a memory for storing the measurements, wherein calculation logic is configured to perform the calculating for each measurement at least for some measurements on the stored measurements.

Example 30. The electronic circuit of example 29, wherein the storing of the measurements comprises storing of the measurements as histograms.

Example 31. The electronic circuit of any one of examples 16 to 30, wherein the electronic circuit is configured to be controlled based on the reliability prediction parameter.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

1. A method comprising:
repeatedly performing a measurement of a plurality of operating parameters of an electronic circuit during operation of the electronic circuit; and
for each measurement: calculating, via the electronic circuit, a reliability prediction parameter of the electronic circuit based on the measurements and a reliability prediction model of the electronic circuit.

2. The method of claim 1, wherein the reliability prediction model is based on a bill of materials of the electronic circuit.

3. The method of claim 1, wherein the reliability prediction model is a standard model or derived thereof.

4. The method of claim 3, wherein the reliability prediction model is according to one of Telcordia SR-332, Mil-HDBK-217, ANSI/VITA 51.1, NPRD/EPRD, IEC 61709, Siemens SN 29500, IEC-TR-62380, FIDES, 217Plus or GJB/Z 299C and GJB/Z 299B.

5. The method of claim 1, wherein the model calculates individual reliability prediction parameters for different components of the electronic circuit and combines the individual reliability prediction parameters to the reliability prediction parameter of the electronic circuit.

6. The method of claim 5, wherein calculating the individual reliability prediction parameters comprises estimating individual operation parameters for the components based on the operation parameters of the electronic circuit, and calculating the individual reliability prediction parameters based on the individual operation parameters.

7. The method of claim 5, comprising grouping the components to subsets, and, for the calculation of the individual reliability prediction parameters, assuming similar operation parameters and/or further parameters for the components of each subset.

8. The method of claim 5, further comprising outputting information about contributions of the different components to the reliability prediction parameter of the electronic circuit.

9. The method of claim 1, wherein the method is implemented in a controller of the electronic circuit.

10. The method of claim 1, wherein the electronic circuit comprises a power converter.

11. The method of claim 1, wherein the method further comprises, for each measurement, updating a cumulative distribution function based on the reliability prediction parameter.

12. The method of claim 11, further comprising outputting a health status based on the updated cumulative distribution function and an expected cumulative distribution function.

13. The method of claim 1, wherein the method comprises storing the measurements, wherein the calculating for each measurement is at least for some measurements performed on the stored measurements.

14. The method of claim 13, wherein the storing of the measurements comprises storing of the measurements as histograms.

15. The method of claim 1, wherein the method further comprises controlling the electronic circuit based on the reliability prediction parameter.

16. An electronic circuit, comprising:
measurement circuitry configured to measure a plurality of operation parameters of the electronic circuit, and
a calculation logic configured to repeatedly calculate a reliability prediction parameter for the electronic circuit based on a respective measurement of the plurality of operation parameters and a reliability prediction model of the electronic circuit.

17. (canceled)

18. A method comprising:
during operation of an electronic circuit, performing measurements of a plurality of operating parameters of the electronic circuit; and
via the electronic circuit, calculating a reliability prediction parameter of the electronic circuit based on: i) the measurements, and ii) a reliability prediction model of the electronic circuit.
